(19) United States
(12) Patent Application Publication
(10) Pub. No.: US 2026/0305446 A1
(43) Pub. Date: Oct. 1, 2026

(54) Systems and Methods for Encapsulation of Semiconductor Devices

(71) Applicant: Sandisk Technologies, Inc., Milpitas, CA (US)

(72) Inventors: Yuanheng Zhang, Shanghai (CN); Jerry Tang, Shanghai (CN); Edison Ai, Shanghai (CN); Yidong Zou, Shanghai (CN); Yonglong Liu, Shanghai (CN); Donghua Wu, Shanghai (CN); Fen Yu, Shanghai (CN); Derek Mong, Kuala Lumpur (MY)

(73) Assignee: Sandisk Technologies, Inc., Milpitas, CA (US)

(21) Appl. No.: 19/091,368

(22) Filed: Mar. 26, 2025

(51) Int. Cl. H01L 21/56; B29C 35/02; H01L 21/67

(52) U.S. Cl. CPC H10W 74/016; B29C 35/0261; H10P 72/0441

(57) ABSTRACT

A semiconductor device encapsulation system includes a mold cavity that receives a molding compound. A heating apparatus is coupled to the mold cavity and heats the molding compound received therein. An integrated physical pre-treatment device is coupled to the mold cavity and removes at least a portion of bubbles formed in the molding compound that is received within the mold cavity. The integrated physical pre-treatment device may reduce the risk of defects occurring during the encapsulation of a semiconductor device in the molding compound.

### BACKGROUND

The present disclosure generally relates to encapsulation of semiconductor device and, more particularly, to systems and methods for encapsulating semiconductor devices in a molding compound.

Semiconductor devices may include a plurality of stacked dies that are encapsulated within a molding compound. For example, a semiconductor device may include a plurality of components such as semiconductor memory dies, controller(s) and bond wires connected to a substrate and encapsulated within a molding compound. The encapsulation of such components may be achieved via a molding process. For example, encapsulation may be achieved via a compression molding process in which a semiconductor device is immersed in a molding compound. However, incomplete filling of the mold compound around the various components of the semiconductor device may cause voids to form resulting in a defective encapsulation. Additionally, during the encapsulation process the mold compound may seep from the mold cavity (e.g., mold bleeding) within which it is received leading to material waste, mold damage and/or a defective encapsulation. Therefore, there is a need to provide systems and methods for encapsulating a semiconductor device that reduce the occurrence of voids and/or the risk of mold bleeding.

### SUMMARY

In one embodiment there is a method of encapsulating a semiconductor device, the method including dispensing a molding compound into a mold cavity, forming bubbles within the molding compound by heating the molding compound in the mold cavity, removing at least a portion of the bubbles from the molding compound during and/or after heating the molding compound by subjecting the molding compound to an integrated physical pre-treatment in the mold cavity, and after subjecting the molding compound to the integrated physical pre-treatment, positioning a semiconductor device within the mold cavity such that one or more components thereof are immersed in the molding compound.

In some embodiments, heating the molding compound causes a volume of the molding compound to expand, and wherein removing at least a portion of the bubbles at least partially counteracts the volume expansion of the molding compound. In some embodiments, subjecting the molding compound to the integrated physical pre-treatment decreases a viscosity of the molding compound. In some embodiments, the integrated physical pre-treatment comprises one or more of acoustic treatment, oscillation treatment, heating regulation, and/or pressure feedback.

In some embodiments, the integrated physical pre-treatment comprises acoustic treatment. In some embodiments, the acoustic treatment causes bubbles within the molding compound to merge into larger bubbles and migrate to a surface of the molding compound. In some embodiments, the molding compound is subjected to the acoustic treatment for a sufficient amount of time to remove at least 90% of bubbles from within the molding compound. In some embodiments, the acoustic treatment is ceased prior to positioning the semiconductor device within the mold cavity. In some embodiments, the semiconductor device is positioned within the mold cavity during the acoustic treatment. In some embodiments, the acoustic treatment is an ultrasonic treatment. In some embodiments, executing the integrated physical pre-treatment causes a density of the molding compound to increase.

In another embodiment there is a semiconductor encapsulation system including a mold cavity configured to receive a molding compound, a heating apparatus coupled to the mold cavity and configured to heat the molding compound received therein, and an integrated physical pre-treatment device coupled to the mold cavity and configured to remove at least a portion of bubbles formed in the molding compound received within the mold cavity.

In some embodiments, the integrated physical pre-treatment device includes a plurality of probes configured to generate acoustic waves, the plurality of probes arranged in an array at a base of the mold cavity. In some embodiments, the integrated physical pre-treatment device is configured to decrease a viscosity of the molding compound received within the mold cavity. In some embodiments, the semiconductor encapsulation system further includes a sensor configured to detect the presence of the bubbles within the molding compound received within the mold cavity.

In some embodiments, the semiconductor encapsulation system further includes a controller in communication with the integrated physical pre-treatment device and the sensor, the controller configured to receive a signal from the sensor indicating the presence of the bubbles within the molding compound, and in response to receiving the signal from the sensor, cause the integrated physical pre-treatment device to generate and transmit acoustic waves into the molding compound. In some embodiments, the semiconductor encapsulation system further includes an energy source in communication with the integrated physical pre-treatment device, a feedback control system configured to monitor at least one of: energy transmitted from the energy source to the integrated physical pre-treatment device, the presence of bubbles within the molding compound, and a viscosity of the molding compound, and a regulation system configured to regulate the energy transmitted to the integrated physical pre-treatment device from the energy source.

In another embodiment there is a semiconductor device encapsulation system including a mold means for receiving a molding compound, a heating means for providing heat to the molding compound, the heating means coupled to the mold means, and an integrated physical pre-treatment means for removing at least a portion of bubbles formed in the molding compound received within the mold means, the integrated physical pre-treatment means coupled to the mold cavity.

In some embodiments, the semiconductor device encapsulation system further includes a sensing means for detecting the presence of bubbles within the molding compound, the sensing means in communication with the integrated physical pre-treatment means. In some embodiments, the semiconductor device encapsulation system further includes a controlling means for controlling operation of the integrated physical pre-treatment means, the controlling means in communication with the sensing means and integrated physical pre-treatment means.

### BRIEF DESCRIPTION OF THE DRAWINGS

The foregoing summary, as well as the following detailed description, will be better understood when read in conjunction with the appended drawings. For the purpose of illustrating the present disclosure, there are shown in the drawings embodiments, which are presently preferred, wherein like reference numerals indicate like elements throughout. It should be noted, however, that aspects of the present disclosure can be embodied in different forms and thus should not be construed as being limited to the illustrated embodiments set forth herein. The elements illustrated in the accompanying drawings are not necessarily drawn to scale, but rather, may have been exaggerated to highlight the important features of the subject matter therein. Furthermore, the drawings may have been simplified by omitting elements that are not necessarily needed for the understanding of the disclosed embodiments.

In the drawings:

FIG. 1 is a diagram illustrating a semiconductor device encapsulation system in accordance with an exemplary embodiment of the present disclosure;

FIG. 2 is a top view of a mold cavity of the system of FIG. 1;

FIGS. 3-7 illustrate the encapsulation of a semiconductor device via the system of FIG. 1 and in accordance with an exemplary embodiment of the present disclosure;

FIG. 8 is a flowchart illustrating a method of encapsulating a semiconductor device in accordance with an exemplary embodiment of the present disclosure.

### DETAILED DESCRIPTION

The present subject matter will now be described more fully hereinafter with reference to the accompanying Figures, in which representative embodiments are shown. The present subject matter can, however, be embodied in different forms and should not be construed as limited to the embodiments set forth herein. Rather, these embodiments are provided to describe and enable one of skill in the art.

Numerous details are described herein in order to provide a thorough understanding of the example embodiments illustrated in the accompanying drawings. However, some embodiments may be practiced without any of the specific details, and the scope of the claims is only limited by those features and aspects specifically recited in the claims. Furthermore, well-known methods, components, and circuits have not be described in exhaustive detail so as not to unnecessarily obscure pertinent aspects of the embodiments described herein.

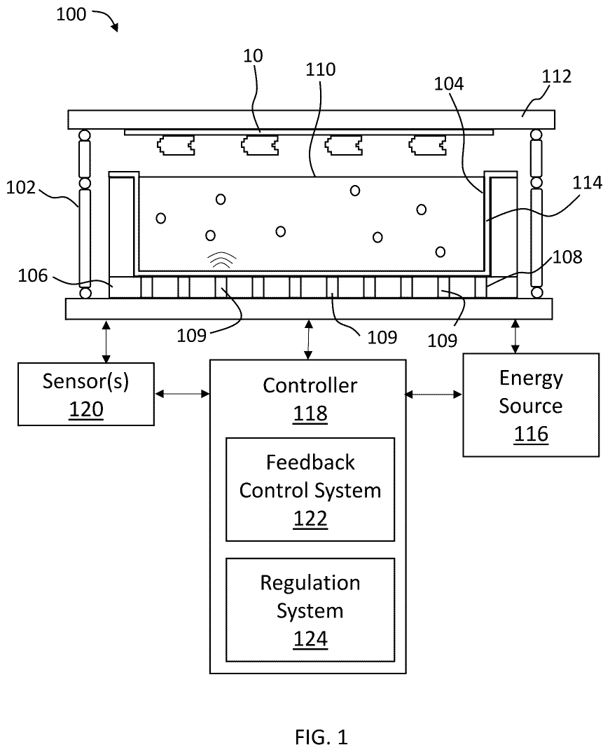

Referring to FIGS. 1-7, there is shown a semiconductor device encapsulation system, generally designated 100, in accordance with an exemplary embodiment of the present disclosure. The system 100 may be configured to decrease the risk of encapsulation related defects as compared to conventional systems.

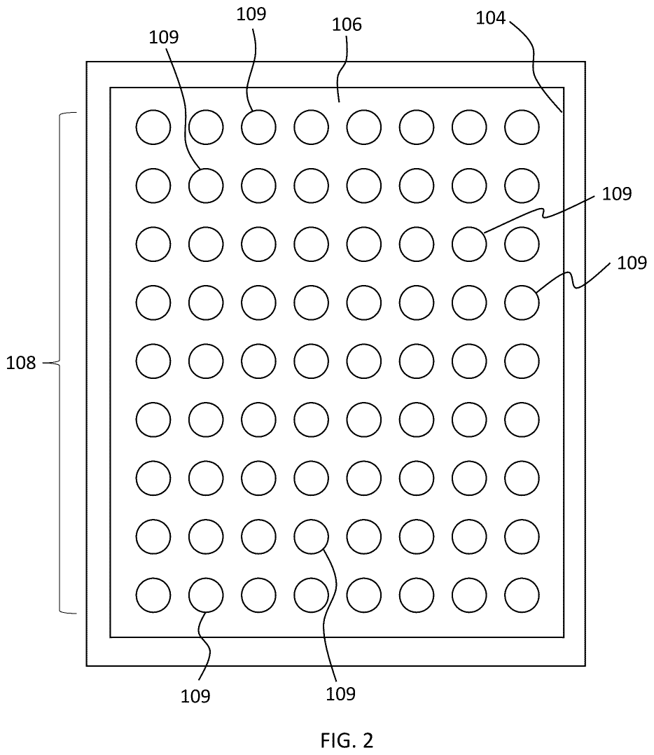

Referring to FIGS. 1-2, the semiconductor device encapsulation system 100, or system 100 for short, may include a mold 102 including a mold cavity 104, a heating apparatus 106 and an integrated physical pre-treatment device 108 (IPPT device 108). In some embodiments, the system 100 includes two or more IPPT devices 108. The mold 102 may be configured to receive a molding compound 110 for use in encapsulating a semiconductor device 10. The mold 102 and/or mold cavity 104 may be a means for receiving a mold compound. The mold cavity 104 of mold 102 may receive the molding compound 110 therein. The mold cavity 104 may be a hollow space support by one or more plates within the mold 102. The mold cavity 104 may be configured to define the external shape of a molded article (e.g., an encapsulated semiconductor device) encapsulated therein. In FIG. 1, a cross-section of the mold 102 is illustrated which depicts a generally rectangular mold cavity 104. Accordingly, a molded article encapsulated within the cavity 104 may have a resulting cuboid shape. However, the mold cavity 104 of the present disclosure is not restricted to a rectangular shape and it should be understood that the mold cavity 104 may take any shape as desired for the shape of a molded article. In some embodiments, the mold cavity 104 defines a composite shape.

In some embodiments, the semiconductor device encapsulation system 100 is a compression molding system configured to encapsulate a semiconductor device 10 with a molding compound 110. The mold cavity 104 may be open on one end and the mold 102 may include a cover 112. The cover 112 may be configured to receive a semiconductor device 10 to be encapsulated by the molding compound 110 contained within the mold cavity 104. In some embodiments, the cover 112 is configured to immerse a semiconductor device 10 coupled thereto in the molding compound 110 received within the mold cavity 104. For example, the cover 112 is movable relative to the mold cavity 104 such that it may translate towards the mold cavity 104 and immerse a semiconductor device 10 in the mold compound 110. The mold 102 may include a compression press configured to control the opening and closing of the cover 112 and/or to apply pressure to the semiconductor device 10 and mold compound 110 during compression molding. In some embodiments, a release film 114 may be positioned within the molding cavity 104 between the surface of the cavity 104 and the molding compound 110. The release film 114 may be configured to prevent the molding compound 110 from adhering to surfaces of the mold 102 during a molding process.

The molding compound 110 may be a molding compound suitable for encapsulation of the semiconductor device 10, as discussed in more detail below. In some embodiments, the molding compound 110 is an epoxy molding compound (EMC). In some embodiments, the semiconductor device 10 may be any semiconductor device for which encapsulation is desired. The semiconductor device 10 may be, but is not limited to, a memory device, a system-in-package (SiP), a storage device (e.g., a secure digital (SD) card or a MultiMediaCard (MMC)), and an integrated circuit (IC). In some embodiments, the semiconductor device 10 may include one or more stacks of memory dies. The memory dies included in a stack may be NAND memory dies. In some embodiments, the semiconductor device 10 may include a controller configured to control the routing of signals (e.g., power, ground, IO signals) to and from the die stacks. The controller and die stacks may be electrically connected to the substrate that serves as a mechanical base support of the semiconductor device 10. In some embodiments, the semiconductor device includes bond wires connecting the die stacks and/or controller to the substrate. In some embodiments, the mold compound 110 may be used to encapsulate components of the semiconductor device 10.

The heating apparatus 106 may be coupled to the mold cavity 104 and configured to heat a molding compound 110 received therein. The heating apparatus may be a heating means for providing heat to the molding compound 110. In some embodiments, the heating apparatus 106 forms a base of the mold cavity 104. For example, the heating apparatus 106 is a heating plate positioned at the base of the mold cavity 104 configured to apply heat to the molding compound 110. In some embodiments, the heating apparatus 106 is configured to apply an active heat treatment to the molding compound 110. For example, the heating apparatus 106 receives energy (e.g., electrical energy) from an energy source 116 to actively generate heat and maintain and/or control the temperature of the molding compound 110. Heating apparatus 106 may be configured to generate heat via resistance wire heating and/or electromagnetic induction heating according to some example embodiments. In some embodiments, the heating apparatus 106 includes a controller (e.g., a proportional-integral-derivative (PID) controller) for temperature regulation. In some embodiments, the system 100 includes a cooling apparatus coupled to the mold cavity 104 and configured to remove heat therefrom. The cooling apparatus may, in some embodiments, utilize a heat transfer fluid to convey heat away from mold cavity 104. The cooling apparatus may include, but is not limited to, a water-cooling system, an air cooling system, and/or an oil cooled system. The cooling apparatus may operate in conjunction with the heating apparatus 106 to regulate temperature of the mold cavity 104. In some embodiments, the cooling apparatus is coupled to the mold 102 and mold cavity 104 in generally the same manner as heating apparatus 106.

In some embodiments, heating of the molding compound 110 causes bubbles of suspended gas to form within the molding compound 110. For example, heating the molding compound 110 via heating apparatus 106 causes the molding compound to begin to melt and undergo a cross-linking reaction, during which bubbles are formed within the molding compound. In conventional encapsulation systems, bubbles formed within a molding compound may negatively impact the encapsulation of a semiconductor device therein. For example, bubbles may remain within a molding compound once it cures thereby creating voids within the hardened mold compound and reducing the structural integrity of the encapsulation.

In some embodiments, the IPPT device 108 is configured to remove at least a portion of bubbles formed in the molding compound 110. The IPPT device may be an integrated physical pre-treatment means for removing at least a portion of bubbles formed within the molding compound 110. The IPPT device 108 may be coupled to the mold cavity 104 and configured to subject the molding compound 110 contained therein to an integrated physical pre-treatment. The integrated physical pre-treatment may cause bubbles formed within the molding compound 110 to be removed therefrom. In some embodiments, removing bubbles from the molding compound 110 via IPPT device 108 may reduce the risk of encapsulation defects from occurring. In some embodiments, the IPPT device 108 is configured to substantially remove bubbles from the molding compound 110. In some embodiments, the IPPT device 108 is configured to remove at least 95% of bubbles from the molding compound 110. In some embodiments, the IPPT device 108 is configured to remove at least 99% of bubbles from the molding compound 110. In some embodiments, the IPPT device 108 is configured to remove all bubbles from the molding compound 110. In some embodiments, the system 100 includes one or more sensors, as discussed in more detail below, configured to measure the amount of bubbles within the molding compound 110. In some embodiment, the amount of bubbles within molding compound 110 may be measured directly by the one or more sensors, and/or may be derived from other properties measured by the one or more sensors. For example, the system 100 may include sensors such as, but not limited to, acoustic measurement sensors, laser measurement sensors, and/or capacitive sensors configured to measure the amount of bubbles within the molding compound 110. In some embodiments, measuring the amount of bubbles may include identifying the location and/or volume of individual bubbles within the molding compound 110.

In some embodiments, the integrated physical pre-treatment is an acoustic treatment. The IPPT device 108 may be configured to generate and transmit acoustic waves into the molding compound 110. In some embodiments, the transmission of acoustic waves into the molding compound 110 may cause at least a portion of the bubbles formed within the molding compound 110 to be removed. The transmission of acoustic waves into the molding compound 110 may cause bubbles within the molding compound to merge into larger bubbles and migrate to the surface of the molding compound. For example, when exposed to an ultrasonic treatment via IPPT device 108, existing bubbles within the molding compound 110 may merge together to form larger bubbles that migrate to the surface of the molding compound 110 and burst. In some embodiments, the transmission of acoustic waves into the molding compound 110 causes bubbles formed within the molding compound 110 to break apart under the cavitation process. In some embodiments, the transmission of acoustic waves into the molding compound 110 causes the bubbles formed within the molding compound 110 to be dissolved. In some embodiments, the IPPT device 108 is configured to generate acoustic waves having a frequency of between about 10 kHz to about 100 kHz. In some embodiments, the acoustic waves are ultrasonic waves.

The IPPT device 108 may include a plurality of probes 109 configured to generate the acoustic waves used to subject the molding compound to the integrated physical pre-treatment. The probes 109 may generate and transmit acoustic waves to the molding compound 110 received within the mold cavity 104. In some embodiments, the plurality of probes 109 are arranged in an array at the base of the mold cavity 104. For example, and as illustrated in FIGS. 1-2, the probes 109 are offset from one another and arranged in a series of rows and columns at the base of the mold cavity 104. In some embodiments, the probes 109 are arranged in an array consisting of between about 5 to 30 rows and about 5 to 30 columns. In some embodiments, the probes 109 are acoustic generators configured to operate during heating of the molding compound 110. The probes 109 may be heat resistant acoustic generators configured to emit acoustic waves while subjected to heat from the heating apparatus 106.

The number and arrangement of the probes 109 along the base of the mold cavity 104 may be selected to achieve a desired coverage of the mold cavity 104. For example, the number and placement of the probes 109 relative to the mold cavity 104 is sufficient such that acoustic waves generated therefrom may permeate at least 95% of a molding compound 110 received within the mold cavity 104. In some embodiments, the plurality of probes 109 are configured to generate acoustic waves sufficient to permeate the entirety of a molding compound 110 received within the mold cavity 104. In some embodiments, the probes are oriented towards the surface of the molding compound 110. In other embodiments, one or more probes 109 are positioned along sidewalls of the mold cavity 104. For example, the probes 109 are positioned at the base of the mold cavity 104 and oriented toward the surface of the mold compound 110 opposite the base such that acoustic waves generated therefrom are directed towards the surface of the mold compound 110.

In some embodiments, the system 100 is configured to control operation of the probes 109 individually and/or by group. The system 100 may be configured to adjust the output of the probes 109 individually or according to desired groupings (e.g., probes 109 positioned within a desired area relative to the mold cavity 104). In some embodiments, system 100 is configured to independently adjust the output of different groups of probes 109. In some embodiments, system 100 is configured to adjust the output of different groups of probes 109 in a particular timing sequence. For example, the system 100 may be configured to first activate probes 109 in a central area of the mold cavity 104 and then activate probes 109 immediately adjacent thereto in sequence such that probe activation starts at the center of the mold cavity 104 and expands outwardly therefrom to the corners.

In some embodiments, the probes 109 are in communication with the energy source 116 and energy transmitted to the probes 109 causes them to generate acoustic waves. In some embodiments, the probes 109 are configured to receive energy from the energy source 116 independent of one another. For example, energy may be transmitted from the energy source 116 to one probe 109 while another probe 109 does not receive power from the power source 116. In some embodiments, energy transmitted to the probes 109 may be regulated by a controller 118 in communication with the IPPT device 108 as discussed in more detail below. In some embodiments, the energy transmitted is electrical energy. The probes 109 may include acoustic transducers configured to transform electrical energy into acoustic energy. In some embodiments, the probes 109 are ultrasonic generators configured to generate ultrasonic waves. In some embodiments, the probes 109 include a piezoelectric element configured to receive electricity and generate ultrasonic waves. In some embodiments, the probes 109 have a diameter of between about 10 mm to about 100 mm. The size of the probes 109 may be selected based on the desired form and/or control thereof.

Subjecting the mold compound to an acoustic treatment, including an ultrasonic treatment, via the IPPT device 108 may cause the mold compound 110 to achieve desired properties for encapsulation of the semiconductor device 10. In some embodiments, subjecting the mold compound 110 to an acoustic treatment may cause the mold compound 110 to form cavitation bubbles, achieve liquid oscillation of the mold compound 110 and/or may promote liquid flow of the mold compound 110 to desired areas within the mold cavity 104. In some embodiments, the IPPT device 108 is configured to subject the molding compound 108 to one or more of an acoustic treatment, oscillation treatment, heating regulation and/or pressure feedback. In some embodiments, the integrated physical pre-treatment may be administered while the semiconductor device 10 is at least partially immersed in the molding compound 110.

In some embodiments, an integrated physical pre-treatment includes an oscillation treatment. An oscillation treatment may include oscillation of the molding compound 110 and/or semiconductor device 10 during encapsulation of the semiconductor device 10. In some embodiments, an oscillation treatment may improve the molding compounds 110 ability to fill structures of the semiconductor device 10. For example, oscillation treatment may improve the molding compounds ability to completely fill tunnels and other structures of the semiconductor device 10.

In some embodiments, the oscillation treatment includes, but is not limited to: mechanical oscillation, ultrasonic oscillation, hydraulic servo oscillation and/or electromagnetic oscillation. In instances where a mechanical oscillation treatment is performed, electromagnetic vibrators (e.g., piezoelectric actuators) may subject the molding compound 110 and/or semiconductor device 10 to a primarily horizontally oriented oscillation at a frequency between, for example, about 10 Hz to about 100 Hz or about 1 kHz to about 10 kHz. In instances where an ultrasonic oscillation treatment is performed, ultrasonic transducers may generate ultrasonic vibrations on the surface of the molding compound thereby subjecting it to a primarily horizontally oriented oscillation at a frequency between, for example, about 20 kHz to about 40 kHz. In instances where a hydraulic servo oscillation treatment is performed, a servo hydraulic system may subject the molding compound 110 and/or semiconductor device 10 to a primarily vertically oriented oscillation at a frequency between, for example, 1 Hz to about 10 Hz. In instances where an electromagnetic oscillation is performed, the molding compound 110 and/or semiconductor device 10 may be subjected to a horizontally and/or vertically oriented oscillation at, for example, a frequency between about 50 Hz to about 100 MHz via one or more of an alternating magnetic field and electromagnetic excitation.

In some embodiments, the integrated physical pre-treatment includes heating regulation. Heating regulation may include adjusting heat supplied to the molding compound 110 at different points in time. In some embodiments, the system 100 is configured to monitor the molding compound 110 and adjust, in real time, the heat supplied to the molding compound 110. In some embodiments, the system 100 is configured to monitor the temperature of the molding compound 110 during heating and/or the integrated physical pre-treatment, and adjust the heat supplied thereto via heating apparatus 106 such that the temperature of the molding compound 110 remains within a desired range or at a desired value. For example, the controller 118 is configured to receive data indicating the temperature of the molding compound and automatically adjust the output of the heating apparatus 106 in order to maintain a desired temperature of the molding compound 110. In some embodiments, the heating regulation may be based on properties of temperature-sensitive material(s) and/or structure(s) of the semiconductor device 10 and/or molding compound 110. For example, the controller 118 is configured to maintain a temperature of the molding compound 110 based at least partially on temperature related properties of the materials and/or structures of the semiconductor device 10.

In some embodiments, the integrated physical pre-treatment may include administering a pressure feedback process to the molding compound 110 and/or semiconductor device 10. A pressure feedback process may include the adjustment of pressure applied to the molding compound 110 and/or semiconductor device 10. The system 100 may be configured to administer a pressure feedback process during encapsulation of the semiconductor device 10 within the molding compound 110. In some embodiments, the controller 118 is configured to measure pressure exerted on the molding compound 110 and/or semiconductor device 10 during encapsulation and adjust the pressure in real time. For example, the controller 118 is configured to monitor in real time the pressure exerted on the molding compound 110 and/or semiconductor device 10 by the mold 102 and adjust the pressure to achieve a desired pressure. In some embodiments, the desired pressure is based at least partially on physical properties of the molding compound 110 and/or semiconductor device 10. For example, modulus of elasticity, toughness, strength, shape and/or other properties of the molding compound 110 and/or semiconductor device 10 may influence the desired pressure to be exerted thereon such that breaks, cracks, deformations or other undesired defects are prevented from occurring.

In some embodiments, the system 100 is configured to detect pressure changes during the molding process (e.g., pressure fluctuations, pressure transitions). Pressure changes may indicate a state of the molding compound 110 and/or semiconductor device 10 during the molding process or the state of a molded product produced by the molding process. The system 100 may be configured to initiate a pressure feedback control process to dynamically adjust pressure in real time. The filling state for structures of the semiconductor device 10 may correspond to pressure changes during the molding process. For example, a filling state of the semiconductor device 10 may be predicted by monitoring pressure changes during the molding process. The system 100 may be configured to, based on a design of the semiconductor device 10, monitor pressure changes via sensors and dynamically adjust the pressure in real-time to achieve adaptive pressure control and compensation. For example, the system 100 is configured to detect one or more of, but not limited to: a pressure starting point (e.g., where a pressure starts to appear, which may affect low-strength and low wire stability structures); a pressure turning point (e.g., a rising or falling pressure value); pressure fluctuations (e.g., corresponding to filling of special structures), and enact dynamic pressure adjustment via real-time monitoring and analyzing the pressure data to achieve adaptive pressure control and compensation. In some embodiments, the system 100 is configured to enact dynamic pressure control, as part of integrated physical pre-treatment, in combination with other integrated physical pre-treatments and corresponding systems as discussed herein to achieve a desired molded semiconductor device.

In some embodiments, the system 100 is configured to apply pressure to the molding compound 110 and/or semiconductor device 10 via a pressure transmission system. The pressure transmission system may be a subassembly of the mold 102. In some embodiments, the pressure transmission system includes a hydraulic drive system and a precision pressure control system configured to dynamically adjust pressure based on feedback data. The hydraulic drive system may include, but is not limited to, hydraulic pumps, servo valves, servo hydraulic cylinders and/or proportional valves. The precision pressure control system may include, but is not limited to, closed-loop control systems, adaptive pressure profiling systems and/or machine learning based optimization systems.

In some embodiments, the system 100 includes a pressure sensing system configured to execute real-time detection of flow pressures and/or hydraulic forces exerted on the molding compound 110 and/or semiconductor device 10. The pressure sensing system may include cavity pressure sensors disposed in the interior of the mold 102 (e.g., mold runners) and/or on the exterior of the mold 102. In some embodiments, the pressure sensing system includes hydraulic pressure sensors. In some embodiments, the pressure sensing system includes one or more of piezoelectric sensors, thin film pressure sensors, strain gauge sensors, and micro-electro-mechanical systems (MEMS).

In some embodiments, the system 100 includes a pressure monitoring system configured to collection pressure sensor data and transmit the pressure sensor data to the pressure transmission system and allow for adjustment of a pressure exerted therefrom. The pressure monitoring system may include, but is not limited to, a data acquisition system (DAO), a programmable logic controller (PIC), and/or a supervisory control and data acquisition system (SCADA).

In some embodiments, the IPPT device 108 is configured to increase the density of the molding compound 110. The removal of bubbles from the molding compound 110, as discussed above, may cause the density of the molding compound 110 to increase. For example, as suspended gases that create voids in the molding compound 110 are dissolved and/or removed therefrom the density of the molding compound 110 increases. The increase in density of the molding compound 110 may reduce the risk of encapsulation related defects.

In some embodiments, the IPPT device 108 is configured to decrease a viscosity of the molding compound 110 received within the mold cavity 102. When subjecting the mold compound 110 to the integrated physical pre-treatment, the IPPT device 108 may cause a viscosity thereof to be decreased. In some embodiments, the transmission of acoustic waves to the mold compound 110 via the IPPT device 108 causes the viscosity of the mold compound 110 to decrease. Reducing the viscosity of the mold compound 110 may decrease the risk of encapsulation related defects. For example, a molding compound 110 of low viscosity may flow more easily around a semiconductor device 10 resulting in fewer voids.

In some embodiments, the system 100 includes a sensor 120 configured to detect the presence of bubbles within the molding compound 110. The sensor 120 may be a sensing means for detecting the presence of bubbles within the molding compound. The sensor 120 may be coupled to the mold 102 and positioned relative to the mold cavity 104 such that it may detect the presence of bubbles that are formed within the mold compound 110. In some embodiments, the system 100 includes a plurality of sensors 120 configured to detect the presence of bubbles in the molding compound 110. In some embodiments, the sensor 120 is an acoustic sensor, an optical sensor, a pressure based sensor, and/or an accelerometer. In some embodiments, the sensor(s) 120 may be configured to measure a viscosity of the molding compound 110. The sensor(s) 120 may be in communications with the controller 118 such that data may be transmitted to the controller 118 from the sensor(s) 120.

In some embodiments, the sensors 120 are configured to determine a discharge rate of bubbles from the molding compound 110. The sensors 120 may be sensors configured to determine the height and/or volume of the molding compound 110. Non-limiting examples of the sensors 120 may include laser, ultrasonic and/or capacitive sensors. The system 100 may be configured to compare the state of bubbles within the molding compound 110 to a height and/or volume of the molding compound to determine a discharge rate of the bubbles therefrom. For example, laser sensors 120 included in the system 100 may determine in real time the location and/or volume of bubbles within the molding compound and/or the height and volume of the molding compound 110. Further to this example, the system 100 may be configured to compare, via controller 118, the height and/or volume of the molding compound 110 with the location and/or volume of bubbles in real time to calculate a discharge rate of the bubbles from the molding compound 110. In some embodiments, the system 100 is configured to adjust the integrated physical pre-treatment of the molding compound 110 based on the calculated discharge rate of bubbles therefrom. For example, the controller 118 may adjust the heat supplied to the molding compound 110 and/or the output of the IPPT device 108 based on the calculated discharge rate.

In some embodiments, the sensors 120 include temperature sensors configured to determine a temperature of the molding compound 110. Non-limiting examples of temperature sensors that may be included in the system 100 include thermocouples and/or infrared sensors. The temperature sensors may be in communication with controller 118 such that temperature data may be transmitted thereto. In some embodiments, the temperature sensors are configured to generate and transmit temperature data to the controller 118 at predetermined intervals and/or in real time.

In some embodiments, the sensors 120 may include pressure measuring sensors configured to measure a pressure exerted on articles positioned within the mold cavity 104 (e.g., the molding compound 110 and/or semiconductor device 10). Non-limiting examples of pressure sensors that may be included in system 100 are piezoelectric and/or strain gauge sensors. The pressure sensors may be in communication with controller 118 such that pressure data may be transmitted thereto. In some embodiments, the pressure sensors are configured to generate and transmit pressure data to the controller 118 at predetermined intervals and/or in real time.

In some embodiments, the sensors 120 may include vacuum sensors configured to measure a vacuum force present within the mold cavity 104. Non-limiting examples of vacuum sensors that may be included in system 100 are capacitive thin-film vacuum gauges, ionizing vacuum gauges, and/or combined vacuum gauges configured to measure gas pressure present within the mold cavity 104. The vacuum sensors may be in communication with controller 118 such that vacuum measurement data may be transmitted thereto. In some embodiments, the vacuum sensors are configured to generate and transmit vacuum measurement data to the controller 118 at predetermined intervals and/or in real time.

In some embodiments, the sensors 120 may include flow sensors configured to monitor a flow of the molding compound 110 within the mold cavity 104. Non-limiting examples of flow sensors that may be included in system 100 are ultrasonic flow sensors, infrared thermal imaging sensors, and/or capacitive sensors. The flow sensors may be in communication with controller 118 such that flow data may be transmitted thereto. In some embodiments, the flow sensors are configured to generate and transmit flow data to the controller 118 at predetermined intervals and/or in real time.

The controller 118 may be configured to control operation of the IPPT device 108 in accordance with one or more methods disclosed herein. The controller 118 may be a controlling means for controlling operation of the IPPT device 108. The controller 118 may be configured to receive a signal from the sensor 120 indicating the presence of bubbles within the molding compound 110 and cause the IPPT device 108 to remove bubbles from the molding compound 110. For example, in response to receiving the signal from sensor 120, the controller 118 causes the IPPT device 108 to generate and transmit acoustic waves into the molding compound 110. In some embodiments, the controller 118 is configured to cause the IPPT device 108 to transmit acoustic waves to the molding compound 110 for an amount of time sufficient to remove at least 90% of the bubbles therefrom. In some embodiments, the controller 118 is configured to cause the IPPT device 108 to transmit acoustic waves to the molding compound 110 for an amount of time sufficient to remove at least 95% of the bubbles therefrom. In some embodiments, the controller 118 is configured to cause the IPPT device 108 to transmit acoustic waves to the molding compound 110 for an amount of time sufficient to remove at least 99% of the bubbles therefrom.

The controller 118 may be configured to store and process data received from sensors 120. In some embodiments, the controller 118 is configured to monitor data generated by the sensors 120 and execute dynamic logic control and real-time adjustment of the integrated physical pre-treatment process performed by the system 100. In some embodiments, the controller 118 is configured to adjust parameters of the integrated physical pre-treatment process such as, but not limited to, the heating, pressure and/or acoustic treatments based on received sensor data. In some embodiments, the controller 118 is PIC. In some embodiments, the controller 118 is a SCADA controller.

In some embodiments, the system 100 includes a feedback control system 122 and a regulation system 124 for monitoring and controlling operation of the heating apparatus 106, IPPT device 108, energy source 116 and/or sensor(s) 120. In some embodiments, the feedback control system 122 and regulation system 124 are included in the controller 118. For example, the controller may be an application specific integrated circuit (ASIC) configured to perform the functionalities discussed herein and the feedback control system 122 and/or regulation system 124 may be subsystems thereof. In other embodiments, the feedback control system 122 and regulation system 124 may be separate from the controller 118. In some embodiments, the feedback control system 122 and/or regulation system 124 may be configured to monitor and control an encapsulation process of the semiconductor device 10. The systems 122, 124 may be configured to monitor pressure, temperature, and volume states of the molding compound 110 during an encapsulation process and dynamically adjust the heating and/or the integrated physical pre-treatment to achieve uniform flow of the molding compound 110, bubble elimination therefrom, and/or to improve the quality of structure filling of the semiconductor device 10.

In some embodiments, the feedback control system 122 is configured to maintain or regulate a desired output of the integrated physical pre-treatment of the system 100. The feedback control system 122 may be configured to monitor the inputs and outputs of the IPPT device 108 to achieve a desired output. The feedback control system 122 may be configured to monitor at least one of: energy transmitted from the energy source 116 to the IPPT device 108, the presence of bubbles within the molding compound 110 and a viscosity of the molding compound. The energy transmitted from the energy source 116 to the IPPT device 108 may be the input to the IPPT device 108 and the presence of bubbles within the molding compound 110 and/or viscosity thereof may be the outputs of the IPPT device 108. The feedback control system 122 may be in communication with the energy source 116 and/or sensor(s) 120. The feedback control system 122 may be configured to monitor the presence of bubbles within the molding compound 110 and/or the viscosity thereof via sensor(s) 120. In some embodiments, the feedback control system 122 is configured to monitor the output of the IPPT device 108 and cause the regulation system 124 to adjust the energy transmitted thereto.

The regulation system 124 may be configured to regulate the energy transmitted to the IPPT device 108 from energy source 116. In some embodiments, the regulation system 124 and feedback control system 122 may be in communication such that the feedback control system 122 causes the regulation system 124 to adjust the energy input to the IPPT device 108. For example, the feedback control system 122 is configured to receive data from sensor(s) 120 indicating the presence of bubbles in the molding compound 110 and cause the regulation system 124 to adjust power supplied to the IPPT device 108 via energy source 116. Further to this example, adjusting the power may be increasing the amount of power supplied to the IPPT device 108 thereby increasing the intensity of acoustic waves emitted by the probes 109. In some instances, adjusting the power to the IPPT device 108 may include supplying power to the probes 109 such that they begin to emit acoustic waves. In some instances, adjusting the power to the IPPT device 108 may include activating or deactivating the IPPT device 108. For example, activating the IPPT device 108 includes supplying energy from the energy source 116 to the probes 109 and deactivating the IPPT device 108 includes ceasing energy from being supplied to the probes 109.

The feedback control system 122 and regulation system 124 may be configured to operate in tandem to adjust the integrated physical pre-treatment that the mold compound 110 is subjected to. The feedback control system 122 may be configured to monitor the presence of bubbles and/or the viscosity of the mold compound 110 and transmit signals to the regulation system 124 to adjust the output of the IPPT device 108 until substantially no bubbles are detected within the mold compound 110 and/or until the mold compound 110 reaches a desired viscosity. In some embodiments, the mold compound 110 is subjected to the integrated physical pre-treatment prior to the semiconductor device 10 being immersed in the mold compound 110 as discussed in more detail below.

In some embodiments, the system 100 is configured to subject the mold compound 110 to heating regulation. The controller 118 may be configured to control operation of the heating apparatus 106 to adjust an amount of heat supplied to the mold compound 110. The controller 118 may be configured to adjust the amount of energy supplied to the heating apparatus 106 by the energy source 116. In some embodiments, the feedback control system 122 is configured to monitor the mold compound 110 and cause regulation system 124 to adjust the energy supplied to the heating apparatus 106. For example, the feedback control system 122 is configured to monitor the presence of bubbles and/or the viscosity of the mold compound and cause the regulation system 124 to adjust power supplied to the heating apparatus 106 until the desired amount of bubbles and/or viscosity is achieved. The feedback control system 122 and/or regulation system 124 may adjust the power supplied to the heating apparatus 106 in generally the same manner as the IPPT device discussed above.

In some embodiments, the controller 118 is configured to adjust power to individual probes 109 of the IPPT device 108. The controller 118, via feedback control system 122 and/or regulation system 124, may be configured to detect the location of bubbles within the mold compound 110 and adjust the output of probes 109 proximate to the bubbles. For example, the sensor(s) 120 determine the location of bubbles and transmit corresponding data indicating that location to the feedback control system 122. Continuing from this example, the feedback control system 122 causes the regulation system 124 to increase power supplied to probes proximate the location indicated in the data transmitted from the sensor(s) 120 thereby causing the located bubbles to be removed from the mold compound. Accordingly, the system 100 of the present disclosure may be configured to focus the integrated physical pre-treatment to localized areas of the mold compound 110.

The system 100 of the present disclosure may be configured to prevent mold bleeding of the mold compound 110 within the mold cavity 104 during heating thereof. In some embodiments, the IPPT device 110 is configured to counteract, at least partially, the effects of heating the mold compound 110 via heating apparatus 106. Heating the mold compound 110 via heating apparatus 106 may cause the volume of the mold compound 110 to expand. The IPPT device 110 may be configured to at least partially counteract the volume expansion of the mold compound 110 by removing bubbles from the mold compound 110 as discussed above. In some embodiments, the system 100 is configured to subject the mold compound 110 to the integrated physical pre-treatment simultaneously as the mold compound 110 is heated by the heating apparatus 106. In some embodiments, the controller 118 is configured to monitor the mold compound 110 during heating and subject the mold compound to the integrated physical pre-treatment to prevent the mold compound 110 from seeping out of the mold cavity 104 (e.g., preventing mold bleeding).

The feedback control system 122 and regulation system 124 may be configured to monitor the mold compound 110 during heating and subject of the mold compound 110 to the integrated physical pre-treatment via IPPT device 108 as discussed above. In some embodiments, the sensor(s) 120 are configured to determine the volume of the mold compound 110 within the mold cavity 104 and transmit data indicated that volume to the controller 118.

In some embodiments, the integrated physical pre-treatment that the mold compound 110 is subjected to via IPPT device 108 may allow for a more broad range of molding compounds to be used for encapsulation of a semiconductor device 10 than in conventional systems. The integrated physical pre-treatment may alter physical properties of a mold compound 110 such as, but not limited to, viscosity, foaming ratio and filling properties thereby allowing for a more wide range of materials to be used as the mold compound than in conventional encapsulation systems. In some embodiments, the integrated physical pre-treatment may enable molding compounds having one or more of: a forming ratio greater than about 150%; a viscosity greater than about 15 Pa·s, and a gel time of less than about 50 seconds, to be used in the encapsulation process.

The mold compound 110 may be dispensed into the mold cavity 104 in the form of, for example, pellets, bullets, powder, granules, and liquid. The composition of the mold compound may include, but is not limited to, filler-free single-component materials, filler single-component materials, and high filler composite materials. In some embodiments, the composition of a molding compound 110 for use with the system may include, but is not limited to, one or more of: epoxy resins (e.g., aliphatic, cycloaliphatic, aromatic); curing agents (e.g., phenols, mercaptans, anhydrides, amines, fatty alcohols); fillers (e.g., silicon dioxide, alumina, manganese oxide and other oxides and nitride materials, graphene, carbon nanorods); toughening agents (e.g., polyimide, polycarbonate, polyphenylene ether and polysulfone); solvents (e.g., acetone, methyl ethyl ketone, methyl isobutyl ketone, cyclohexanone and other ketones, ethylene glycol dibutyl ether, butyl fiber solvent acetate); flame retardants; catalysts; and stress relaxation additives. In some embodiments, the properties of the mold compound 110 selected may be suitable such that a resulting encapsulated semiconductor device is protected from the external environment, resistant to external solvents, moisture, shock and is electrically insulated from the external environment.

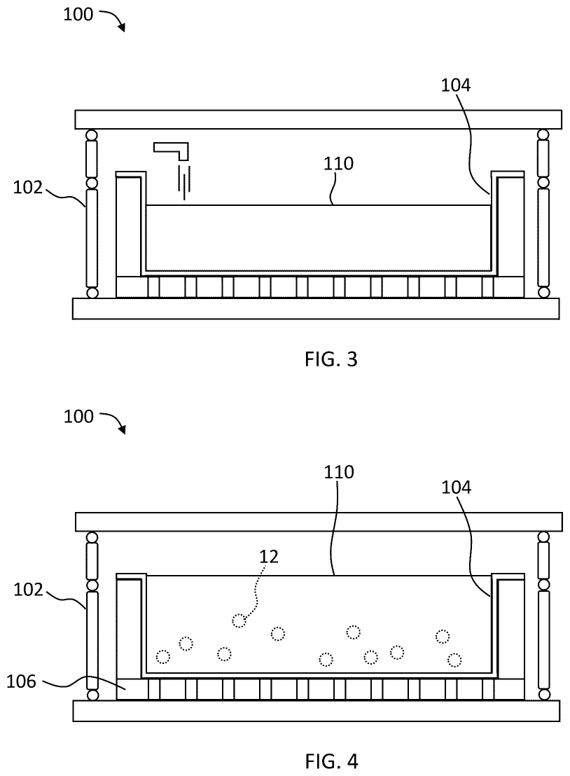

Referring to FIGS. 3-7, there is shown an encapsulation of a semiconductor device 10 via the system 100 in accordance with an exemplary embodiment of the present disclosure. In FIG. 3, the mold compound 110 is dispensed into the mold cavity 104. In FIG. 3, dispensing of the mold compound 110 is illustrated as flowing a liquid mold compound 110 into the mold cavity 104, however other suitable methods known in the art may be used. In FIG. 4, bubbles 12 are formed within the molding compound 110 by heating the mold compound 110. In some embodiments, the heating apparatus 106 is activated in FIG. 4 causing bubbles 12 to form within the mold compound 110. As illustrated, and discussed above, the volume of the mold compound 110 may increase as the mold compound 110 is heated.

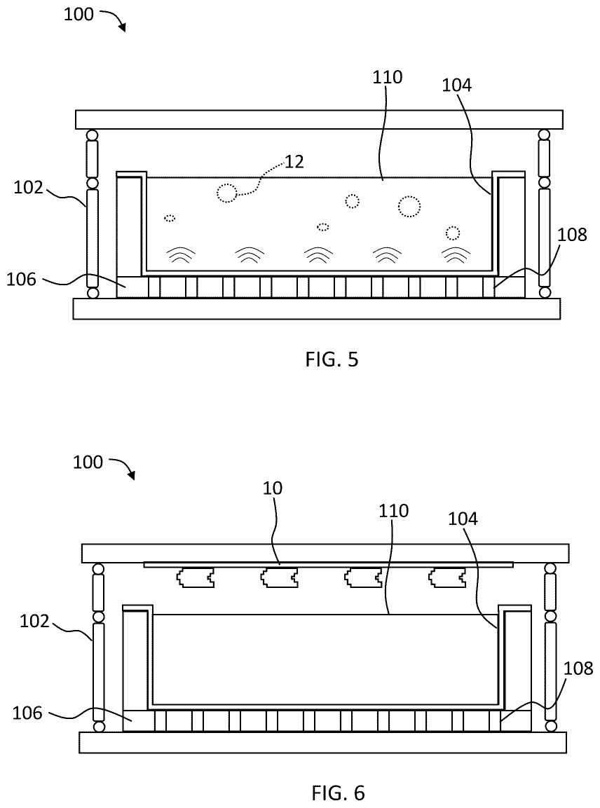

In FIG. 5, at least a portion of the bubbles 12 are removed from the molding compound 110 during and/or after heating the molding compound 110 by subjecting the molding compound 110 to an integrated physical pre-treatment in the mold cavity 104. The IPPT device 108 may be activated (e.g., via the controller 118 discussed above) in order to subject the mold compound 110 to the integrated physical pre-treatment. As illustrated in FIG. 5, subjecting the mold compound 110 to the integrated physical pre-treatment, as discussed above, causes at least a portion of the bubbles 12 to be removed. In some embodiments, and as discussed above, subjecting the mold compound 110 to the integrated physical pre-treatment at least partially counteracts the volume expansion of the mold compound 110. In some embodiments, the heating apparatus 106 continues to heat the molding compound 110 while the molding compound 110 is subjected to the integrated physical pre-treatment. In some embodiments, the integrated physical pre-treatment is an acoustic treatment, as discussed above.

In FIG. 6, the molding compound 110 is subjected to the integrated physical pre-treatment until substantially all of the bubbles have been removed therefrom and/or a desired viscosity of the mold compound 110 is achieved, as discussed above. In FIG. 6 the integrated physical pre-treatment is complete and the resulting treated mold compound 110 is prepared for encapsulation of the semiconductor device 10. The semiconductor device 10 may be positioned within the mold 102 to be encapsulated in the treated mold compound 110. For example, in FIG. 6 the semiconductor device 10 has been mounted to the cover 112. In other instances, the semiconductor device 10 is coupled to the mold 102 prior to the completion of the integrated physical pre-treatment.

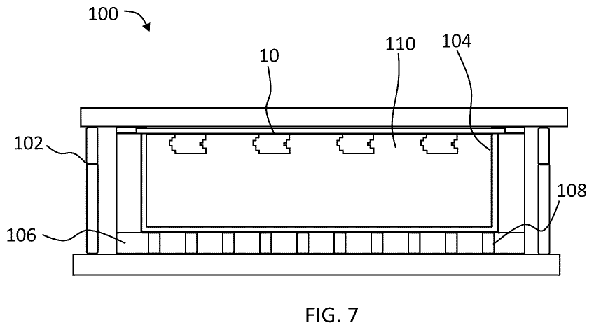

In FIG. 7, the semiconductor device 10 is positioned within the mold cavity 104 such that the components thereof are immersed in the molding compound 110. In some embodiments, the semiconductor device 10 is positioned within the mold cavity 104 after subjecting the molding compound 110 to the integrated physical pre-treatment. In some embodiments, the semiconductor device 10 is subjected to compression molding following the integrated physical pre-treatment of the mold compound 10 to form an encapsulated semiconductor device package. In some FIG. 7, the semiconductor device 10 is positioned within the mold cavity 104 after the acoustic treatment of the integrated physical pre-treatment is ceased. In other embodiments, an acoustic treatment may be executed on the mold compound 110 while the semiconductor device 10 is positioned within the mold cavity 104 to aid in encapsulation. For example, the acoustic treatment may decrease viscosity of the mold compound 110, as discussed above, thereby allowing the mold compound 110 to more freely flow around the components of the semiconductor device 10. Following what is illustrated in FIG. 7, the encapsulated semiconductor device 10 may be removed from the mold 102 for further processing as desired.

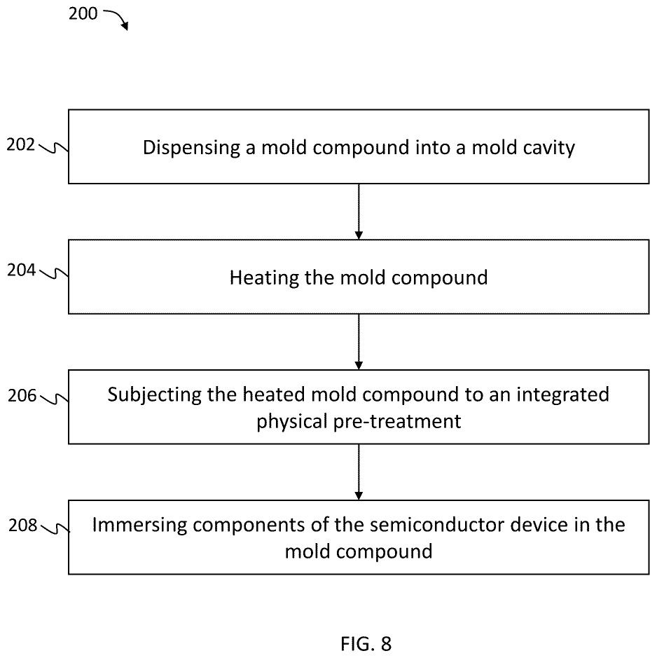

Referring to FIG. 8, there is shown a flowchart illustrating a method, generally designated 200, of encapsulating a semiconductor device in accordance with an exemplary embodiment of the present disclosure. The method 200 may include the step 202 of dispensing a molding compound into a mold cavity. For example, and as discussed above with regards to FIG. 3, the mold compound 110 may be dispensed into mold cavity 104. The method 200 may include the step 204 of forming bubbles within the molding compound by heating the molding compound in the mold cavity. For example, and as discussed above with regards to FIG. 4, bubbles 12 are formed in the mold compound by heating the mold compound 110 via heating apparatus 106.

The method 200 may include the step 206 of removing at least a portion of the bubbles from the molding compound during and/or after heating the molding compound by subjecting the molding compound to an integrated physical pre-treatment in the mold cavity. For example, and as discussed above with regards to FIGS. 5-6, the IPPT device 104 subjects the mold compound 110 to an integrated physical pre-treatment that causes at least a portion of the bubbles 12 to be removed therefrom. In some embodiments, at least 90% of the bubbles are removed from the mold compound 110. In some embodiments, between about 90% to about 100% of the bubbles are removed from the molding compound 110.

The method 200 may include the step 208 of, after subjecting the molding compound to the integrated physical pre-treatment, positioning a semiconductor device within the mold cavity such that one or more components thereof are immersed in the molding compound. For example, and as discussed above with regards to FIG. 7, the semiconductor device 10 is positioned within mold cavity 104 such that the one or more components of the semiconductor device 10 are immersed in the molding compound 110. In some embodiments, encapsulating a semiconductor device in accordance with the method 200 reduces the risk of encapsulation related defects such as voids in the molding compound and/or reduces the risk of mold bleeding, as discussed above.

It will be appreciated by those skilled in the art that changes could be made to the exemplary embodiments shown and described above without departing from the broad inventive concepts thereof. It is understood, therefore, that this invention is not limited to the exemplary embodiments shown and described, but it is intended to cover modifications within the spirit and scope of the present invention as defined by the claims. For example, specific features of the exemplary embodiments may or may not be part of the claimed invention and various features of the disclosed embodiments may be combined. The words “right”, “left”, “lower” and “upper” designate directions in the drawings to which reference is made. Unless specifically set forth herein, the terms “a”, “an” and “the” are not limited to one element but instead should be read as meaning “at least one”. As used herein, the term “about” may refer to +/−10% of the value referenced. For example, “about 9” is understood to encompass 8.1 and 9.9.

It is to be understood that at least some of the figures and descriptions of the invention have been simplified to focus on elements that are relevant for a clear understanding of the invention, while eliminating, for purposes of clarity, other elements that those of ordinary skill in the art will appreciate may also comprise a portion of the invention. However, because such elements are well known in the art, and because they do not necessarily facilitate a better understanding of the invention, a description of such elements is not provided herein.

Further, to the extent that the methods of the present invention do not rely on the particular order of steps set forth herein, the particular order of the steps should not be construed as limitation on the claims. Any claims directed to the methods of the present invention should not be limited to the performance of their steps in the order written, and one skilled in the art can readily appreciate that the steps may be varied and still remain within the spirit and scope of the present invention.

What is claimed is:

1. A method of encapsulating a semiconductor device, the method comprising:
dispensing a molding compound into a mold cavity;
forming bubbles within the molding compound by heating the molding compound in the mold cavity;
removing at least a portion of the bubbles from the molding compound during and/or after heating the molding compound by subjecting the molding compound to an integrated physical pre-treatment in the mold cavity; and
after subjecting the molding compound to the integrated physical pre-treatment, positioning a semiconductor device within the mold cavity such that one or more components thereof are immersed in the molding compound.

2. The method of claim 1, wherein heating the molding compound causes a volume of the molding compound to expand, and wherein removing at least a portion of the bubbles at least partially counteracts the volume expansion of the molding compound.

3. The method of claim 1, wherein subjecting the molding compound to the integrated physical pre-treatment decreases a viscosity of the molding compound.

4. The method of claim 1, wherein the integrated physical pre-treatment comprises one or more of acoustic treatment, oscillation treatment, heating regulation, and/or pressure feedback.

5. The method of claim 1, wherein the integrated physical pre-treatment comprises acoustic treatment.

6. The method of claim 5, wherein the acoustic treatment causes bubbles within the molding compound to merge into larger bubbles and migrate to a surface of the molding compound.

7. The method of claim 6, wherein the molding compound is subjected to the acoustic treatment for a sufficient amount of time to remove at least 90% of bubbles from within the molding compound.

8. The method of claim 5, wherein the acoustic treatment is ceased prior to positioning the semiconductor device within the mold cavity.

9. The method of claim 5, wherein the semiconductor device is positioned within the mold cavity during the acoustic treatment.

10. The method of claim 5, wherein the acoustic treatment is an ultrasonic treatment.

11. The method of claim 1, wherein executing the integrated physical pre-treatment causes a density of the molding compound to increase.

12. A semiconductor device encapsulation system comprising:
a mold cavity configured to receive a molding compound;
a heating apparatus coupled to the mold cavity and configured to heat the molding compound received therein; and
an integrated physical pre-treatment device coupled to the mold cavity and configured to remove at least a portion of bubbles formed in the molding compound received within the mold cavity.

13. The semiconductor device encapsulation system of claim 12, wherein the integrated physical pre-treatment device includes a plurality of probes configured to generate acoustic waves, the plurality of probes arranged in an array at a base of the mold cavity.

14. The semiconductor device encapsulation system of claim 12, wherein the integrated physical pre-treatment device is configured to decrease a viscosity of the molding compound received within the mold cavity.

15. The semiconductor device encapsulation system of claim 12 further comprising a sensor configured to detect the presence of the bubbles within the molding compound received within the mold cavity.

16. The semiconductor device encapsulation system of claim 13 further comprising a controller in communication with the integrated physical pre-treatment device and the sensor, the controller configured to:
receive a signal from the sensor indicating the presence of the bubbles within the molding compound; and
in response to receiving the signal from the sensor, cause the integrated physical pre-treatment device generate and transmit acoustic waves into the molding compound.

17. The semiconductor device encapsulation system of claim 14 further comprising:
an energy source in communication with the integrated physical pre-treatment device;
a feedback control system configured to monitor at least one of: energy transmitted from the energy source to the integrated physical pre-treatment device, the presence of bubbles within the molding compound, and a viscosity of the molding compound; and
a regulation system configured to regulate the energy transmitted to the integrated physical pre-treatment device from the energy source.

18. A semiconductor device encapsulation system comprising:
a mold means for receiving a molding compound;
a heating means for providing heat to the molding compound, the heating means coupled to the mold means; and
an integrated physical pre-treatment means for removing at least a portion of bubbles formed in the molding compound received within the mold means, the integrated physical pre-treatment means coupled to the mold cavity.

19. The semiconductor device encapsulation system of claim 18 further comprising:
a sensing means for detecting the presence of bubbles within the molding compound, the sensing means in communication with the integrated physical pre-treatment means.

20. The semiconductor device encapsulation system of claim 19 further comprising:
a controlling means for controlling operation of the integrated physical pre-treatment means, the controlling means in communication with the sensing means and integrated physical pre-treatment means.
